(19) United States
(12) Patent Application Publication
(10) Pub. No.: US 2005/0112473 A1
(43) Pub. Date: May 26, 2005

(54) Photomask for enhancing contrast

(76) Inventors: Wen-Tien Hung, Taipei City (TW); Chin-Lung Lin, Hsinchu Hsien (TW); Chuen-Huei Yang, Taipei City (TW)

Correspondence Address: J C PATENTS, INC., 4 VENTURE, SUITE 250, IRVINE, CA, 92618, US

(21) Appl. No.: 10/721,153

(22) Filed: Nov. 24, 2003

(51) Int. Cl. G03C 5/00; G03F 9/00

(52) U.S. Cl. 430/5; 430/322; 430/323; 430/324

(57) ABSTRACT

The present invention provides a photomask comprising a substrate and a plurality of shielding patterns. The substrate comprising a plurality of shielding regions and a plurality of transparent regions, while each transparent region is disposed between two adjacent shielding regions and has one depression. The depression and the shielding region share a same edge and a sidewall of the depression is aligned with a sidewall of the shielding pattern.

### BACKGROUND OF THE INVENTION

1. Field of Invention

The present invention relates to a photomask used in the photolithography process. More particularly, the present invention relates to a photomask for enhancing contrast in images.

2. Description of Related Art

Photolithography and etching are key technologies in the fabrication of integrated circuits, for transferring predetermined patterns to the layers over the semiconductor substrate or the wafer. In the conventional photolithography process, a photoresist layer is formed over the semiconductor substrate and then exposed through a photomask, thus transferring the pattern of the photomask to the photoresist layer. After developing the photoresist layer, a pattern that is complementary to or equivalent to the pattern of the photomask is formed in the photoresist layer.

Referring to FIG. 1, the photomask 100 used in the conventional lithography process is composed of a transparent (light transmitting) quartz substrate 12 and an opaque patterned chromium layer 14 thereon. During the exposure process, light will transmit through the aperture 16 (the quartz substrate not covered by the chromium layer) to illuminate (expose) the corresponding photoresist layer over the semiconductor substrate. Theoretically, light will not pass through the locations covered by the chromium layer 14, so that locations of the photoresist layer corresponding to the chromium layer are not exposed. However, because of diffraction by the apertures, certain locations of the photoresist layer corresponding to the chromium layer are partially exposed, as shown in FIG. 2. As the patterns of the integrated circuits become more compact, the apertures in the patterns of the photomask become smaller and the interference is more serious. In other words, as the device is minimized, the contrast of the images is not satisfactory to provide enough resolution and uniformity for the critical dimensions by using the conventional photomask in the lithography process.

In order to augment the exposure quality in the prior art, the phase shifting technology is employed. For the conventional phase shifting technology, a phase-shifting layer designed to cover adjacent apertures of the photomask leads to a 180-degree phase change of the light, thus canceling the diffraction between adjacent apertures. In general, the phase-shifting masks include Levenson type, shifter-only type and assist slot type masks.

As shown in FIG. 3, the Levenson type mask 300, also called an alternate type mask, includes a plurality of phase-shifting layers 18 formed alternatively on the apertures 16 between the chromium layer 14 on the substrate 12. For the shifter-only type mask 400, referring to FIG. 4, the phase shifting layer 18 alone exists on the substrate 12. For the assist slot type photomask 500, shown in FIG. 5, one slot 24 is formed in each of two adjacent chromium layers (patterns) 14 and one phase-shifting layer 18 is formed covering the slot 24. Although definite improvements can be obtained from the phase-shifting masks, the fabrication processes for the masks are difficult and complex.

### SUMMARY OF THE INVENTION

The present invention provides a photomask for enhancing contrast in images, to afford higher resolution and uniformity for the critical dimensions.

The present invention relates to a photomask for enhancing contrast in images. The fabrication processes of the photomasks are simplified and the yields of the photomasks are increased.

As embodied and broadly described herein, the present invention relates to a photomask comprising a substrate and a plurality of shielding patterns. The substrate comprising a plurality of shielding regions and a plurality of transparent regions, while each transparent region is disposed between two adjacent shielding regions and has one depression. The shielding patterns are disposed on the shielding regions. The depression and the shielding region share a same edge and a sidewall of the depression is aligned with a sidewall of the shielding pattern.

As embodied and broadly described herein, the present invention provides a photomask comprising a substrate and a plurality of shielding patterns. The substrate comprises a dense pattern region and a loose pattern region, while the dense pattern region and the loose pattern region respectively comprises a plurality of shielding regions and a plurality of transparent regions. The shielding patterns are disposed on the shielding regions. Each transparent region is disposed between two adjacent shielding regions and has one depression. The depression and the shielding region share a same edge and a sidewall of the depression is aligned with a sidewall of the shielding pattern.

Because the depression in the transparent region causes destructive interference for canceling the diffraction, the intensity of the electric field at the wafer corresponding to the shielding patterns approaching to approximately zero. Therefore, the contrast of the images is enhanced and higher resolution and uniformity for the critical dimension are obtained.

Furthermore, in the fabrication processes of the photomask, one shielding layer is formed on the substrate. After patterning the shielding layer, the substrate is etched to form the plurality of depressions and the fabrication is completed. The fabrication of the photomask is pretty easy. Moreover, because the etching depth of the substrate can be readily controlled, the yield of the photomask is greatly increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a prior art photomask.

FIG. 2 is a display view of the electric field at the wafer for the photomask of FIG. 1.

FIG. 3 is a cross-sectional view of the Levenson type photomask.

FIG. 4 is a cross-sectional view of the shifter-only type photomask.

FIG. 5 is a cross-sectional view of the assist slot type photomask.

FIG. 6 is a cross-sectional view of the attenuate type photomask.

FIG. 7 is a cross-sectional view of the rim type photomask.

FIG. 8 is a cross-sectional view of the attenuate rim type photomask.

FIG. 9A is a cross-sectional view of the photomask according to one preferred embodiment of this invention.

FIG. 9B is a cross-sectional view of the photomask according to another preferred embodiment of this invention.

FIG. 10 is a display view of the electric field at the wafer for the photomask of FIG. 9A when the shielding pattern is opaque.

FIG. 11 is a display view of the electric field at the wafer for the photomask of FIG. 9A when the shielding pattern is composed of the slightly translucent phase-shifting layer.

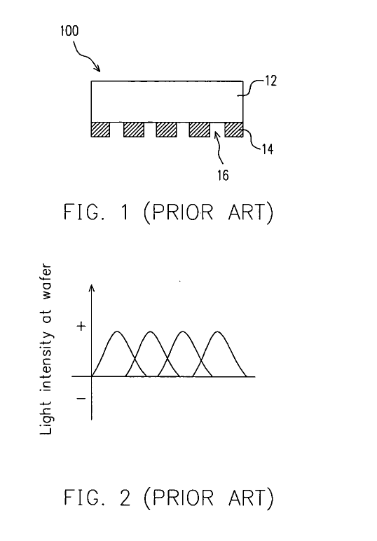

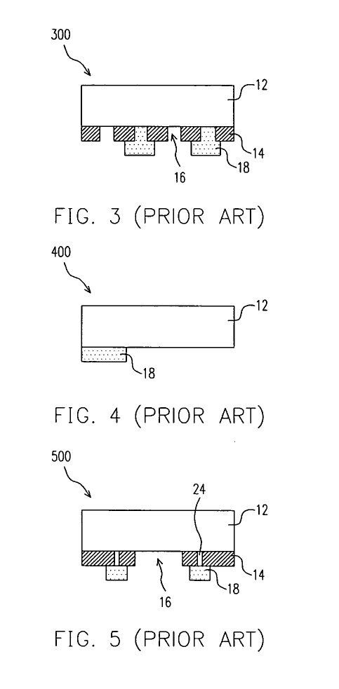

### DESCRIPTION OF THE PREFERRED EMBODIMENTS

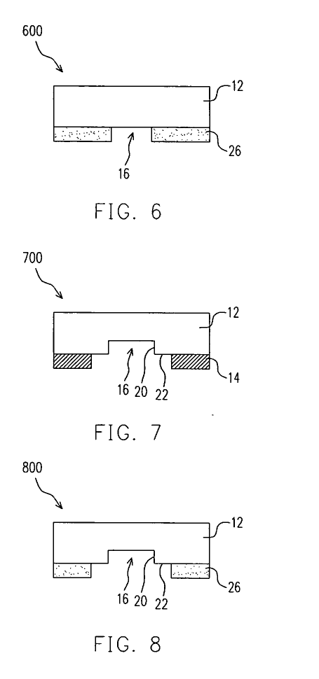

According to the preferred embodiments of this invention, different designs and several kinds of photomasks are described. FIG. 6 is a cross-sectional view of the attenuate type photomask. For the attenuate type mask 600 in FIG. 6, the phase-shifting layer 26 having a transmittance rate of about 4-10% is formed on the quartz substrate 12 to form the desired patterns. The phase-shifting layer can act for both an absorptive layer and a phase-shifting layer. FIG. 7 is a cross-sectional view of the rim type photomask. As seen in FIG. 7, the rim type photomask 700, after forming the chromium layer (having patterns) 14 on the quartz substrate 12, a trench 20 is etched into the substrate 12 in the midst of the gap 16 between the patterns 14. The trench 20 is able to generate a 180-degree phase change, because the quartz substrate 12 around the edge of the gap 16 (the flat region 22) is not etched. The rim type mask 700 employs the phase difference between the trench 20 in the midst of the gap 16 and the flat region 22 to cancel the diffraction around the edge of the gap 16, thus enhancing the resolution of the images. FIG. 8 is a cross-sectional view of the attenuate rim type photomask. In the attenuate rim type photomask 800, a phase-shifting layer 26 having a transmittance rate of 4-10% is formed on the quartz substrate 12 to form the desired patterns and a trench 20 is etched into the substrate 12 in the midst of the gap 16 between the patterns of the phase-shifting layer 26. The trench 20 is able to generate a 180-degree phase change, because the quartz substrate 12 around the edge of the gap 16 (the flat region 22) is not etched. The attenuate rim type mask 800 possesses the advantages of both the attenuate type mask and the rim type mask, and its attenuate regions (regions covered with the phase-shifting layer) can utilizes interference to cancel the diffraction around the edge of the apertures.

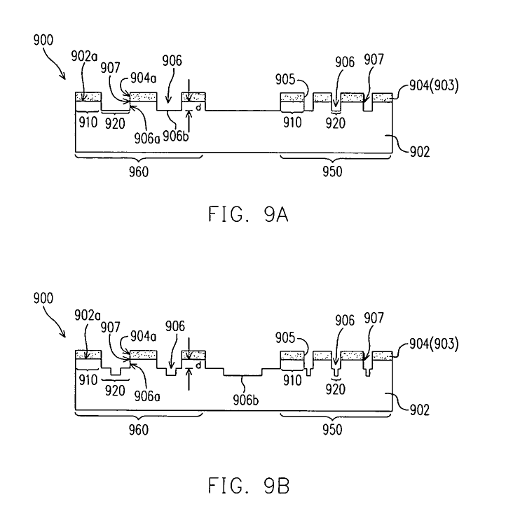

FIG. 9A is a cross-sectional view of the photomask according to one preferred embodiment of this invention, while FIG. 9B is a cross-sectional view of the photomask according to another preferred embodiment of this invention. Referring to FIG. 5, the photomask 900 includes a transparent substrate 902 and a plurality of shielding patterns 904 on the substrate 902. The substrate 902 is a transparent crystalline quartz substrate, for example. The substrate 902 at least includes a dense pattern region 950 and loose pattern region 960, while the dense pattern region 950 and loose pattern region 960 comprise a plurality of shielding regions 910 and a plurality of transparent regions 920. Each transparent region 920 is disposed between two adjacent shielding regions 910. The shielding patterns 904 are disposed on the shielding regions 910 of the substrate 902. The material of the shielding pattern 904 can be an opaque material. The opaque material can be chromium metal, for example. Alternatively, the material of the shielding pattern 904 can be a translucent material. The slightly translucent material can be molybdenum silicide, for example. The slightly translucent material has the transmittance rate of 4-10%, preferably 5-10%, and also acts as a phase shifter, for example.

According to the preferred embodiments, by using the shielding patterns 904 as etching masks, a plurality of depressions 906 is etched into the substrate 902 in the transparent regions 920. Each depression 906 is disposed in each transparent region 920 and between the two adjacent shielding patterns 904. The depression can be a trench, a hole or a cavity, and in a shape of the strip, the square, the rectangle, the circle or even the triangle, for example. The cross-sectional view of the depression 906 is in a U shape, a reverse trapezium shape, or a rectangle shape. The cross-section of the depression 906 can even be a T shape, as shown in FIG. 9B, depending on the design of the mask. Each depression 906 occupies the whole transparent region 920. That is, the depression 906 shares the same edge 907 with the shielding region 910 and the sidewall 906a of the depression 906 (also the edge 907) is aligned with the sidewall 904a of the shielding pattern 904. The bottom surface 906b of the depression 906 in each transparent region 920 is lower than the top surface 902a of the substrate 902, so that a height difference d is between the bottom surface 906b and the surface of the substrate 902 (i.e. the depression 906 having a depth d).

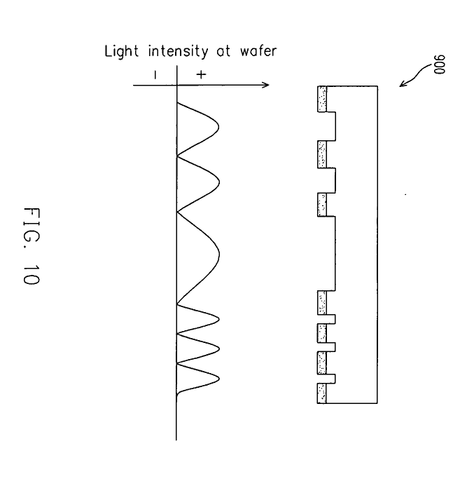

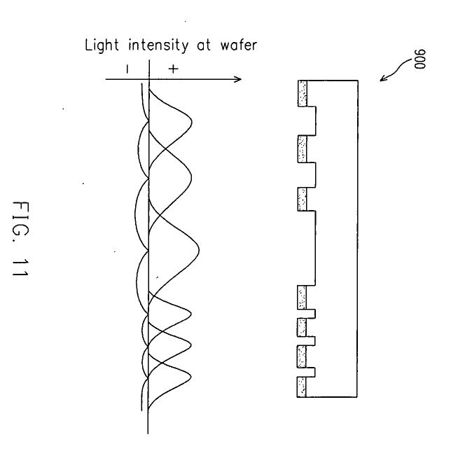

If the shielding pattern 904 is made of the opaque material, light does not transmit through the shielding pattern 904 but passes through the transparent region 920 (in other words, passing through the depression 906 in the transparent region 920). The depression 906 in the transparent region 920 causes light passing through the edges of the shielding patterns 904 to produce destructive interference for canceling the diffraction, thus causing the intensity of the electric field at the wafer corresponding to the shielding patterns 904 approaching to approximately zero, as shown in FIG. 10. For example, the height difference d between the bottom surface 906b and the surface of the substrate 902 is able to cause a 180-degree phase change, when the cross-sectional view of the depression is a rectangle shape.

If the shielding pattern 904 is made of the slightly translucent material, light passes through the transparent region 920 (in other words, passing through the depression 906 in the transparent region 920), while part of light also passes through the shielding pattern 904 to produce a 180-degree phase change, relative to the depression 906. The depression 906 in the transparent region 920 causes light passing through the edges of the shielding patterns 904 to produce destructive interference for canceling the diffraction, thus causing the intensity of the electric field at the wafer corresponding to the shielding patterns 904 approaching to approximately zero, as shown in FIG. 11. For example, the height difference d between the bottom surface 906b and the surface of the substrate 902 is able to generate a 360-degree phase change, when the cross-sectional view of the depression is a rectangle shape.

Because the depression in the transparent region causes destructive interference for canceling the diffraction, the intensity of the electric field at the wafer corresponding to the shielding patterns approaching to approximately zero. Therefore, the contrast of the images is enhanced and higher resolution and uniformity for the critical dimension are obtained.

In addition, the fabrication processes of the above described photomasks comprise forming one shielding layer on the substrate and then patterning the shielding layer to form the plurality of the shielding patterns. Using the shielding patterns as etching masks, the substrate is etched to form the plurality of depressions. The fabrication processes are not complex and easy to control. Moreover, because the etching depth of the substrate can be readily controlled, the yield of the photomask is greatly increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A photomask, comprising:
a substrate, the substrate comprising a plurality of shielding regions and a plurality of transparent regions, wherein each transparent region is disposed between two adjacent shielding regions and has one depression, and wherein the depression and the shielding region share a same edge; and
a plurality of shielding patterns disposed on the shielding regions of the substrate, wherein a sidewall of the depression is aligned with a sidewall of the shielding pattern.

2. The photomask of claim 1, wherein the shielding pattern is made form an opaque material.

3. The photomask of claim 2, wherein the opaque material includes chromium.

4. The photomask of claim 2, wherein a cross-section of the depression is in a rectangle shape.

5. The photomask of claim 4, wherein a distance between a bottom surface of the depression and a surface of the substrate is allows a generation of a 180-degree phase shift.

6. The photomask of claim 1, wherein the shielding pattern is made from a slightly translucent material with a transmittance rate of 5-10%.

7. The photomask of claim 4, wherein the slightly translucent material includes molybdenum silicide.

8. The photomask of claim 6, wherein a cross-section of the depression is in a rectangle shape.

9. The photomask of claim 8, wherein a distance between a bottom surface of the depression and a surface of the substrate is allows a generation of a 360-degree phase shift.

10. The photomask of claim 1, wherein a cross-section of the depression is in a rectangle shape.

11. The photomask of claim 1, wherein a cross-section of the depression is in a T shape.

12. A photomask, comprising:
a substrate, the substrate comprising a dense pattern region and a loose pattern region, wherein the dense pattern region and the loose pattern region respectively comprise a plurality of shielding regions and a plurality of transparent regions, wherein each transparent region is disposed between two adjacent shielding regions and has one depression, and wherein the depression and the shielding region share a same edge; and
a plurality of shielding patterns disposed on the shielding regions of the substrate, wherein a sidewall of the depression is aligned with a sidewall of the shielding pattern.

13. The photomask of claim 12, wherein the shielding pattern is made form an opaque material.

14. The photomask of claim 13, wherein the opaque material includes chromium.

15. The photomask of claim 13, wherein a cross-section of the depression is in a rectangle shape.

16. The photomask of claim 15, wherein a distance between a bottom surface of the depression and a surface of the substrate allows a generation of a 180-degree phase change.

17. The photomask of claim 12, wherein the shielding pattern is made from a slightly translucent material with a transmittance rate of 5-10%.

18. The photomask of claim 17, wherein the slightly translucent material includes molybdenum silicide.

19. The photomask of claim 17, wherein a cross-section of the depression is in a rectangle shape.

20. The photomask of claim 19, wherein a distance between a bottom surface of the depression and a surface of the substrate allows a generation of a 360-degree phase change.

21. The photomask of claim 12, wherein a cross-section of the depression is in a rectangle shape.

22. The photomask of claim 12, wherein a cross-section of the depression is in a T shape.
